(19) United States
(12) Patent Application Publication
(10) Pub. No.: US 2024/0337943 A1
(43) Pub. Date: Oct. 10, 2024

(54) HIGH REFRACTIVE INDEX PHOTORESIST COMPOSITION

(71) Applicant: Dow Silicones Corporation, Midland, MI (US)

(72) Inventors: Peng-Fei Fu, Midland, MI (US); Wonbum Jang, Jincheon-gun (KR); John Ell, Midland, MI (US); Myunhwa Chung, Jangheung-gun (KR)

(21) Appl. No.: 18/575,890

(22) PCT Filed: Aug. 1, 2022
(86) PCT No.: PCT/US2022/039032

§ 371 Date: Jan. 2, 2024

Related U.S. Application Data
(60) Provisional application No. 63/255,974, filed on Oct. 15, 2021.

(51) Int. Cl. G03F 7/075; C08G 77/38

(52) U.S. Cl. CPC G03F 7/0757; C08G 77/38

(57) ABSTRACT

A composition contains a photocurable resin that has a weight-average molecular weight of 3000-50000 Daltons, a glass transition temperature of at least 100 degrees Celsius and contains the following siloxane units: 50-80 mole-percent (HSiC>3/2). 10 to 30 mole-percent (R*SiC>3/2), 10 to 40 mole-percent (Ar*SiC>3/2), and 20.0 mole-percent or less of Si—OZ content, where mole-percent values are relative to moles of silicon atoms in the photocurable resin, R* is a photocurable group. Ar* in each occurrence is selected from a group of halogen-substituted aryl groups and polyaryl groups: Z in each occurrence is selected from hydrogen and alkyl groups. and subscripts x and y are independently in each occurrence either one or 2.

### FIELD OF THE INVENTION

The present invention relates to a photoresist resin, a negative photoresist composition comprising the photoresist resin and a method for using the negative photoresist composition.

### INTRODUCTION

There are two approaches to creating optical light emitting diode (OLED) displays. A first approach is to pattern a relatively low refractive index (RI) negative photoresist composition to create lens patches on diode pixels and then fill in around the lens patches with a relatively high RI planarization polymer. A second possible approach is to pattern a relatively high RI photoresist composition to create lens patches on RGB diode pixels and then fill in around the lens patches with a lower RI planarization polymer. Companies are requesting photoresist compositions for preparing OLED displays using this second approach, but there are challenges with the second approach.

A challenge with the second approach is finding a photoresist resin with a high enough RI to form a negative photoresist composition that has a high enough RI to be suitable for creating the lens patches. The RI difference between the relatively high RI negative photoresist composition for the lens material and the relatively low planarization polymer should be at least 0.10. A typical planarization polymer has an RI of 1.45 (RI values herein are measured at 632 nm and 21-23 degrees Celsius), so the negative photoresist composition must have an RI of at least 1.55. A suitable photoresist resin capable of being formulated into an acceptable negative photoresist composition that can be spin-coated onto a substrate, so the photoresist resin must have a weight-average molecular weight of greater than 3,000 and 100,000 Daltons or less, preferably in a range of 5,000 to 20,000 Daltons so it can form a uniform coating. The photoresist resin must also have a glass transition temperature (Tg) of at least at least 10 degrees Celsius (° C.) above baking temperature for the photoresist so that the photoresist resin will not be sticky and lacking desired mechanical properties, which means the glass transition temperature of the photoresist resin should be 100° C. or higher. The photoresist resin must be photocurable, especially photocurable into a pattern through a photomask, and must also be soluble in developer materials such as tetramethylammonium hydroxide (TMAH) solutions to remove uncured material to leave a pattern cured material.

It is desirable to provide a photoresist resin that meets the requirements for use as a photoresist in making OLED displays according to the second approach.

### BRIEF SUMMARY OF THE INVENTION

The present invention provides a photoresist resin that is suitable for preparing a negative photoresist composition that meets the requirements for use as a photoresist in making OLED displays by first patterning a negative photoresist composition as lens patches on RGB diode pixels and then planarizing with a lower RI planarization polymer, and a process for making such OLED displays.

The present invention is a result of discovering how to prepare a photoresist resin with a high enough RI so as to be suitable as the photoresist resin in a negative photoresist composition that has a RI of 1.55 or higher, where the photoresist resin has a weight-average molecular weight in a range of 3,000 to 50,000 Daltons, a Tg of at least 100° C. and demonstrates solubility in TMAH solution. Moreover, the photoresist resin (and negative photoresist composition) achieves these properties while containing less than 20.0 mole-percent (mol %) Si—OZ content relative to silicon atom content, and can achieve these properties even with 1.0 mol % or less Si—OZ content, where “Si—OZ” refers to hydroxyl and alkoxyl groups bound to silicon atoms. Other photoresist resins contain higher amounts of Si—OH to achieve solubility in the basic developer solutions. The present invention is a result of discovering what combination of functional groups are required to prepare such a photoresist resin and, particularly, what concentration ranges of each functional group are needed to achieve these properties. In particular, it was discovered that SiH content is required to achieve the basic developer solution solubility.

Additionally, small silane molecules (weight-average molecular weight of less than 500 Daltons) and/or organic resins with pendant silyl groups on the organic polymer backbone can be avoided in the composition to prevent potential outgassing issues associated with such molecules from contaminating optical lenses. Small silane molecules can outgas during baking or during exposure to light during curing. Similarly, organic resins with pendant silyl groups can undergo cleavage of the silyl groups during baking or exposure to light during curing and the cleaved groups can outgas. Outgassing molecules are undesirable because they can contaminate other components in the process. Fortunately, the resins and compositions of the present invention can be fee of small silane molecules and/or organic resins with pendant silyl groups.

In a first aspect, the present invention is a composition comprising a photocurable resin, wherein the photocurable resin has a weight-average molecular weight in a range of 3,000-50,000 Daltons, a glass transition temperature of at least 100 degrees Celsius and comprises the following siloxane units: 50-80 mole-percent (HSiO_{3/2}), 10 to 30 mole-percent (R*SiO_{3/2}), 10 to 40 mole-percent (Ar*SiO_{3/2}), and less than 20.0 mole-percent Si—OZ content, where mole-percent values are relative to moles of silicon atoms in the photocurable resin. R* is a photocurable group, Ar* in each occurrence is selected from a group of halogen-substituted aryl groups and polyaryl groups; Z in each occurrence is selected from hydrogen and alkyl groups, and subscripts x and y are independently in each occurrence either one or 2. The composition can be a negative photoresist composition that comprises 10 to 50 weight-percent of the photoresist resin of any one previous claim, one to 3 weight-percent of a photoinitiator at a concentration, and 49-89 weight-percent of a solvent, where weight-percentages are relative to photoresist composition weight. The photocurable resin can have 1.0 mole-percent or less Si—OZ content.

In a second aspect, the present invention is a process for using a negative photoresist composition version of the first aspect to prepare an optical light emitting diode display, the process comprising the following steps: (a) providing a substrate that comprises multiple diodes; (b) coating the negative photoresist composition onto the substrate that comprises multiple diode pixels; (c) exposing the negative photoresist composition that resides over the diode pixels to light to cure the photoresist resist resin in the negative photoresist composition to form lens patches over the diode pixels; (d) rinsing away the unexposed/uncured negative photoresist composition with an aqueous alkali solution; (e) applying a planarization polymer over the substrate and lens patches; and (f) curing the planarization polymer.

The photoresist resin and negative photoresist composition of the present invention is useful for preparing OLED articles according to the process of the present invention.

### DETAILED DESCRIPTION OF THE INVENTION

Test methods refer to the most recent test method as of the priority date of this document when a date is not indicated with the test method number. References to test methods contain both a reference to the testing society and the test method number. The following test method abbreviations and identifiers apply herein: ASTM refers to ASTM International methods; EN refers to European Norm; DIN refers to Deutsches Institut für Normung; ISO refers to International Organization for Standards; and UL refers to Underwriters Laboratory.

Products identified by their tradename refer to the compositions available under those tradenames on the priority date of this document.

“Multiple” means two or more. “And/or” means “and, or as an alternative”. All ranges include endpoints unless otherwise indicated. Unless otherwise stated, all weight-percent (wt %) values are relative to composition weight and all volume-percent (vol %) values are relative to composition volume.

Siloxane units have the following terminology in the present application, where each O_{1/2} corresponds to an oxygen shared with another siloxane unit and identified in the other siloxane unit also with an O_{1/2}. For instance, a molecule with the chemical structure (R₃SiO_{1/2})₂ corresponds to R₃SiOSiR₃ where the O_{1/2} of each siloxane unit correspond to a single oxygen atom. “Q” type siloxane units have the chemical structure (SiO_{4/4}), meaning it is a silicon atom attached through oxygens to four other siloxane units. “T” type siloxane units have the chemical structure (RSiO_{3/4}) where R is a hydrogen, hydrocarbyl, or some other group attached to a silicon atom that is attached to three other siloxane units through oxygen atoms. “D” type siloxane units have the chemical structure (RR′SiO_{3/4}) where each of R and R′ are hydrogen, hydrocarbyl, or some other group attached to a silicon atom that is attached to two other siloxane units through oxygen atoms. “M” type siloxane units have the chemical structure (RR′R″SiO_{1/2}) where each of R, R′ and R″ are hydrogen, hydrocarbyl, or other group attached to a silicon atom that is attached to another siloxane unit through an oxygen atom.

Determine resin structures using nuclear magnetic resonance (NMR) spectral analysis. Record NMR spectra using a Varian XL-400 spectrometer. Reference chemical shifts for ¹H, ¹³C and ²⁹Si spectra to an internal solvent resonance and report relative to tetramethylsilane.

“Molecular weight” refers to weight-average molecular weight unless otherwise indicated herein. Determine weight-average molecular weight and polydispersity (PDI) by gel permeation chromatograph (GPC) using a Waters 600 pump, a Waters 717 autosampler and a Waters 410 differential refractometer.

Determine glass transition temperature (Tg) for a resin using a DSC-Q2000 instrument by loading 6-10 milligrams of dry resin (resin dried in a vacuum oven at 80° C. and 133 pascal (one millimeter mercury) for 10 hours) into a sample dish and measuring by ramping from 23° C. to 200° C. at a rate of 10° C. per minute.

The composition of the present invention comprises and can consist of a photocurable resin. The photocurable resin comprises and can consist of the following siloxane units: (HSiO_{3/2}), (R*SiO_{3/2}), (Ar*SiO_{3/2}) and optionally (ZO)ₓ(R*)SiO_{(3-x)/2} and/or (ZO)_{y}(Ar*)SiO_{(3-y)/2} units where:
R* is a photocurable group, and is preferably in each occurrence independently selected from a group consisting of epoxy-containing groups, acrylate-containing groups, acryloxy groups, vinylether groups, and vinyl groups. Desirably, each R* group is independently in each occurrence selected from a group consisting of epoxycyclohexylethyl group (“CHEp” group), glycidoxypropyl group (“Ep” group), and methacryloxypropyl group (“MA” group). Within the same molecule, each R* group can be the same or they can be different.
Ar* is selected from a group consisting of halogen-substituted aryl groups and polyaryl groups. Desirably, each Ar* group is independently in each occurrence selected from a group consisting of those having the following chemical structures (i)-(v):

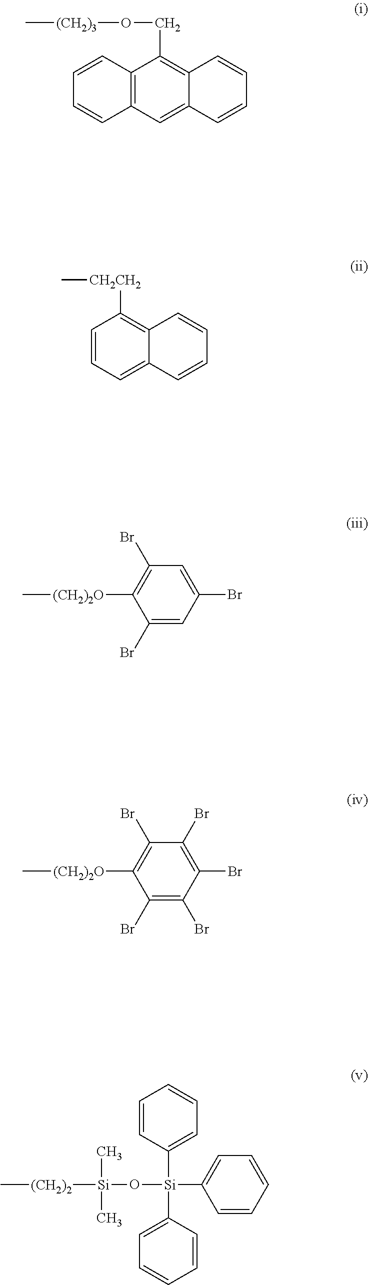

For convenience herein, chemical structure use the following abbreviations for the above Ar* groups: (i) is “An”, (ii) is “Naph”, (iii) is “TBP”, (iv) is “PBP”; and (v) is “TPS”.
Z is independently in each occurrence selected from hydrogen and alkyl groups. Desirably, the alkyl groups have one or more, and can be 2 or more, 3 or more, 4 or more, 5 or more, even 6 or more carbon atoms while at the same time typically contain 8 or fewer, 7 or fewer, 6 or fewer, 5 or fewer, 4 or fewer, 3 or fewer, even 2 or fewer carbon atoms. Desirably, Z is independently in each occurrence selected from a group consisting of hydrogen, methyl, and ethyl groups.
Subscripts x and y are independently in each occurrence either 1 or 2.

The photoresist resin of the present invention desirable has the following average chemical structure (I):

(HSiO_{3/2})ₐ(R*SiO_{3/2})_{b}(Ar*SiO_{3/2})_{c}[(ZO)ₓ(R*)SiO_{(3-x)/2}]_{d}[(ZO)_{y}(Ar*)SiO_{(3-y)/2}]ₑ (I)

where:
R*, Ar*, Z and subscripts x and y are as previously defined.
Subscript a is the average mole-ratio of (HSiO_{3/2}) siloxane units in the resin and has a value of 0.50 or more and can be 0.60 or more, even 0.70 or more while at the same time is typically 0.80 or less, and can be 0.70 or less, or even 0.60 or less relative to total moles of siloxane units in the resin.
Subscript b is the average mole-ratio of (R*SiO_{3/2}) siloxane units in the resin and has a value of 0.10 or more, and can be 0.15 or more, 0.20 or more, even 0.25 or more while at the same time is typically 0.30 or less, 0.25 or less, 0.20 or less, or even 0.15 or less relative to total moles of siloxane units in the resin.
Subscript c is the average mole-ratio of (Ar*SiO_{3/2}) siloxane units in the resin and has a value of 0.10 or more, and can have a value of 0.20 or more, even 0.30 more, while at the same time typically has a value of 0.40 or less, 0.30 or less, or even 0.20 or less relative to total moles of siloxane units in the resin.
Subscript d is the average ratio of (ZO)ₓ(R*) SiO_{(3-x/2)} siloxane units in the resin and subscript e is the average mole-ratio of (ZO)_{y}(Ar*)SiO_{(3-y/2)} siloxane units in the resin and where the sum of subscripts d and e has a value of zero or more, and can be greater than zero, 0.001 or more, even 0.005 or more and at the same time is typically sufficiently low such that the total Si—OZ content is 20 mol % or less, 18 mol % or less, 16 mol % or less, 14 mol % or less, 12 mol % or less, 10 mol % or less, 8 mol % or less, 6 mol % or less, 4 mol % or less, 2.0 mol % or less, desirably 1.0 mol % or less, even 0.5 mol % or less or even 0.1 mol % or less based on moles of Si atoms in the resin. Generally, the sum of subscripts d and e is 0.20 or less, 0.18 or less, 0.16 or less, 0.15 or less, 0.12 or less, 0.10 or less, 0.08 or less, 0.06 or less, 0.04 or less, 0.03 or less, 0.02 or less and desirably is 0.01 or less, and can be 0.005 or less, even 0.001 or less relative to total moles of siloxane units in the resin. Subscripts x and y are independently in each occurrence either one or 2.
The sum of the values for subscripts a, b, c, d, and e is 1.00 (that is, desirably a+b+c+d+e=1.00).

The photoresist resin, and the composition as a whole, can be free of unsaturated carbon-carbon bonds (that is, carbon-carbon double and triple bonds).

Desirably, the composition is a negative photoresist composition that comprises or consists of the photoresist, a photoinitiator, a solvent, and optionally up to 2 wt % additional additives.

The negative photoresist composition typically comprises photoresist resin at a concentration of 10 wt % or more and can contain 20 wt % or more, 30 wt % or more, even 40 wt % or more while at the same time typically comprises 50 wt % or less, and can comprise 40 wt % or less, 30 wt % or less, even 20 wt % or less of the photoresist resin relative to the negative photoresist composition weight.

The negative photoresist composition typically comprises a photoinitiator at a concentration of one wt % or more, or 2 wt % or more while at the same time typically 3 wt % or less, and can be 2 wt % or less with wt % relative to the negative photoresist composition weight.

When the photocurable group R* is an epoxy-containing group or a vinylether groups, the photoinitiator is a cationic photoinitiator (also referred to as a photoacid generator or PAG). The cationic photoinitiator is a chemical that undergoes actinic decomposition upon exposure of light. Upon this decomposition, an active cationic species and an anionic species are generated. In other words, the cationic photoinitiator comprises an active cationic species and an anionic species. In some embodiments, the cationic species includes an onium salt. The onium salt may include a diaryliodonium salt, a triarylsulfonium salt, or a tetraaryl phosphonium salt. In some embodiments, the anionic species is selected from the group of BF₄—, PF₆—, AsF₆—, SbF₆—, and (C₆F₅)₄B—. Examples of PAGs include bis(4-dodecylphenyl)iodonium hexafluoroantimonate; (p-dodecylphenyl)(p-methylphenyl)iodonium hexafluoroantimonate; (p-isopropylphenyl)(p-methylphenyl)iodonium tetrakis(pentafluorophenyl) borate; diphenyliodonium nitrate, diphenyliodonium hexafluorophosphate, (4-fluorophenyl)diphenylsulfonium triflate, N-hydroxynaphthalimide triflate, (4-iodophenyl)diphenylsulfonium triflate, (4-methoxyphenyl)diphenylsulfonium triflate, (4-phenoxyphenyl)diphenylsulfonium triflate, triarylsulfonium hexafluorophosphate, triphenyl sulfonium perfluoro-1-butanesulfanate, triphenyl sulfonium triflate, tris(4-tert-buityphenyl)sulfonium perflulro-1-butanesulfonate, bis(4-tert-butylphenyl)iodonium perfluoro-1-butanesulfonate, and bis(4-tert-butylphenyl)iodonium p-toluenesulfonate.

When the photocurable group R* is an acrylate-containing groups, acryloxy groups, or vinyl groups. The photoinitiator is a free-radical photoinitiator. The free-radical photoinitiator is a chemical that undergoes actinic decomposition upon exposure of light. Upon this decomposition, active free radicals are generated to induce the polymerization of acrylate-containing groups, acryloxy groups, or vinyl groups. The free-radical photoinitiator is not limited and can be selected from any known free radical type photo-initiator effective for promoting crosslinking reactions. Examples of the (b) photoinitiator include diethoxyacetophenone (DEAP), benzoin methyl ether, benzoin ethyl ether, benzoin isopropyl ether, diethoxyxanthone, chloro-thioxanthone, azo-bisisobutyronitrile, N-methyl diethanolaminebenzophenone 4,4′-bis(dimethylamino)benzophenone, diethoxyacetophenone, 2,2-dimethoxy-1,2-diphenylethan-1-one, 1-hydroxycyclohexyl-phenyl-ketone, 2-hydroxy-2-methyl-1-phenylpropan-1-one, 2-methyl-1-[4-(methylthio)phenyl]-2-morpholinopropan-1-one, 1-[4-(2-hydroxyethoxy)phenyl]-2-hydroxy-2-methyl-propan-1-one, 2-benzyl-2-dimethylamino-1-(4-morpholinophenyl)butan-1-one, bis(2,4,6-trimethylbenzoyl)phenylphosphine oxide, 2-hydroxy-2-methyl-1-phenyl-propan-1-one, 2-dimethylamino-2-(4-methyl-benzyl)-1-(4-morpholin-4-yl-phenyl)-butan-1-one, and combinations thereof.

The negative photoresist composition comprises a solvent at a concentration that is typically 49 wt % or more and can be 50 wt % or more, 60 wt % or more, 70 wt % or more, even 80 wt % or more, while at the same time is typically 89 wt % or less, or even 80 wt % or less, 70 wt % or less, 60 wt % or less, or even 50 wt % or less with wt % relative to negative photoresist composition weight. Examples of suitable solvents in include methyl ethyl ketone (MEK), methyl isobutyl ketone (MIBK), 2-heptanone, methyl pentyl ketone (MAK), cyclopentanone, cyclohexanone, lactate alkyl esters like ethyl lactate, 1,2-propylene glycol monomethyl ether monoacetate (PGMEA), alkylene glycol monoalkyl esters, butyl acetate, 2-ethoxyethanol, and ethyl 3-ethoxypropionate.

The negative photoresist composition can comprise additional additives such as any one or any combination of more than one additive selected from sensitizers, surfactants, and quenchers. Sensitizers are useful to enhance activity of the photoinitiator by absorbing radiation at a first wavelength and emitting radiation at a second wavelength transferring the emitted ration to the photoinitiator. Surfactants are useful to improve uniformity of a coating of the composition on a substrate or underlayer on a substrate. Quenchers include basic materials such as organic amines. Suitable quenchers including compounds listed in paragraphs 306 to 315 of US2003/0017415, organic base additives mentioned in U.S. Pat. No. 8,148,043, and oxaamines found in U.S. Pat. No. 10,990,012. Specific examples include tertiary arylamines such as 2-(2-aminophenyl)-isoindole-1,3-dione; 1-(2-((1H-1,2,3-benzotriazol-1-ylmethyl)amino)phenyl)ethanone; 1-((2,3-dimethyl-phenylamino)-methyl)-pyrrolidine-2,5-dione; 1-(2-methyl-4-phenylamino-3,4-dihydro-2H-quinolin-1-yl)-heptan-1-one; 2-((3-fluoro-4-methyl-phenylamino)-methyl)-phenol, N,N-diethylaniline; tri(1-methyl-ethanol-2-yl)-amine; tri(2-(3′-methylbutyloxy)ethyl)-amine; tri(2-(hexyloxy)ethyl)-amine; tri(2-(methoxymethoxy)ethyl 1)-amine. The combined concentration of additional additives can be zero wt % or more, even one wt % or more while at the same time is typically 2 wt % or less, or even one wt % or less relative to negative photoresist composition weight.

The process of the present invention is a process for preparing an optical light emitting diode display where the process comprises the following steps: (a) providing a substrate, such as a silicon wafer, that comprises multiple diode pixels; (b) coating the negative photoresist composition described herein onto a substrate the substrate that comprises multiple diode pixels; (c) exposing the negative photoresist composition that resides over the diode pixels to light to cure the photoresist resin in the negative photoresist composition to form lens patches over the diode pixels; (d) rinsing away the unexposed/uncured negative photoresist composition with an aqueous alkali solution; (e) applying a planarization polymer over the substrate and lens patches; and (f) curing the planarization polymer.

Step (b) desirably includes spin-coating the negative photoresist composition of the present invention onto the substrate. Alternative suitable methods for applying the negative photoresist composition onto a substrate include spray coating, dip coating, slit coating and gravery coating.

Step (c) desirably includes exposing the negative photoresist composition to light through a mask to selectively expose certain portions of the negative photoresist composition to light to cause curing of the photoresist in the negative photoresist composition that is exposed to the light. Preferably, the mask only allows exposure of negative photoresist composition portions residing over diode pixels so that the photoresist cures into lens patches over the diode pixels.

Step (d) occurs after step (c) and involves rinsing away uncured negative photoresist composition from the substrate thereby leaving only the cured portions. Accomplish the rinsing with an aqueous alkali solution. Desirably, the aqueous alkali solution comprises tetramethylammonium hydroxide in water (2.35 to 2.62 wt % concentration). Other examples of the aqueous alkali solution are choline, sodium hydroxide, potassium hydroxide, sodium carbonate, sodium silicate, sodium metasilicate, ammonia, ethylamine, propylamine, diethylamine, dipropylamine, triethylamine, methyldiethylamine, ethyldimethylamine, triethanolamine, pyrrole, piperidine, 1,8-diazabicyclo[5.4.0]-7-undecene, and 1,5-diazabicyclo[4.3.0]-5-nonene.

The planarization polymer is a curable polymer that is applied over the cured photoresist on the substrate and fills in the spaces between the cured photoresist portions to form a planar surface over the substrate. The planarization polymer can be applied by spin coating, spray coating, dip coating, slit coating, or gravery coating. After applying the planarization polymer, cure it to form a cured polymeric coating on the substrate.

The cured planarization polymer desirably has a RI that is at least 0.1 lower than the RI of the negative photoresist composition. The negative photoresist composition and the photoresist resin, cured or non-cured, has a RI of 1.55 or greater and can be 1.60 or greater, 1.65 or greater. Determine RI by ellipsometry using 632 nanometer light at 21-23° C.

### Examples

Table 1 identifies the materials for use in preparing the following examples.

TABLE 1

| Component | Source |
|---|---|
| Allyl glycidyl ether | Sigma-Aldrich |
| 4-vinyl-1-cyclohexene 1,2-epoxide | Sigma-Aldrich |
| 9-(hydroxymethyl)anthracene | Sigma-Aldrich |
| Sodium hydroxide | Sigma-Aldrich |
| 3-bromopropene | Sigma-Aldrich |
| vinylnaphthalene | Sigma-Aldrich |
| 9-vinylanthracene | Sigma-Aldrich |
| 1,1,-dimethyl-3,3,3-triphenyl-1- | Gelest |
| vinyldisiloxane | |
| Trichlorosilane | Sigma-Aldrich |
| 2,4,6-tribromophenylallyl ether | Sigma-Aldrich |
| Pentabromophenyl allyl ether | Sigma-Aldrich |
| 1,4-butanediol vinyl ether | Sigma-Aldrich |
| Toluene | Sigma-Aldrich |
| Propylene glycol methyl ether acetate | Sigma-Aldrich |
| (“PGMEA”) | |
| Karstedt's Platinum catalyst | Gelest |
| (p-Isopropylphenyl)(p- | Gelest |
| methylphenyl)iodonium | |
| tetrakis(pentafluorophenyl)borate | |
| Triethoxysilane | Gelest |
| 1-napthyltrimethoxysilane | Gelest |
| Dibutyltin dilaurate (“DBTDL”) | Gelest |
| Photoinitiator 1 (C₂₆H₂₇O₃P) | Available as IRGACURE ™ |
| | 819 from BASF |
| (3- | Available as DOWSIL ™ Z- |
| glycidyloxypropyl)trimethoxysilane | 6040 from The Dow Chemical |
| | Company |
| Methacryloxypropyl trimethoxysilane | Available as DOWSIL ™ Z- |
| | 6030 from The Dow Chemical |
| | Company |
| (p-isopropylphenyl)(p- | Gelest |
| methylphenyl)iodonium | |
| tetrakis(pentafluorophenyl)borate | |

IRGACURE is a trademark of BASF SE Company. DOWSIL is a trademark of The Dow Chemical Company.

### Hydrosilsesquioxane (HSQ) Resin Synthesis

Prepare the HSQ Resin using a controlled hydrolysis of trichlorosilane in the presence of concentrated sulfuric acid in toluene following the teachings in Frye, C.L.; Collins, W.T.; J. Am. Chem. Soc. 92 (19); 1970, 5586-5588. The HSQ Resin has a weight average molecular weight of 2,200 and a polydispersity index of 2.78. The moles of hydroxy and alkoxy relative to moles of silicon is less than 0.1 wt %.

### 9-Allyloxyanthracene Synthesis

Prepare 9-allyloxyanthracene (CAS #125340 Nov. 6) by reaction of 208.3 g of 9-(hydroxymethyl)anthracene (Sigma-Aldrich), 121.0 g of 2-bromopropene (Signa-Aldrich) and 1.5 g of sodium hydroxide in 500 g of toluene at 70° C. for 6 hours. After 6 hours, cool the mixture to 25° C. and neutralize with acetic acid and then filter. Remove volatiles by rotovap at 40° C. Recrystallize in ethanol to a yellow crystalline powder. ¹H-NMR (CDCl₃): d 8.42; (m, 3H), 8.02; (d, 2H), 7.50; (m, 4H), 6.10; (m, 1H), 5.41 (S, 2H), 5.38 (d, 1H), 5.25; (d, 1H), 4.20; (d, 2H).

### (3-(Anthracen-9-ylmethoxy)propyl)triethoxysilane Synthesis

Prepare (3-(Anthracen-9-ylmethoxy) propyl) triethoxysilane by reacting of 9-allyloxyanthracene (22.2 g) and triethoxysilane (16.5 g) in the presence of a Karstedt's Platinum catalyst (0.02 g) in toluene (100g) at 60° C. for 3 hrs. After the completion of the reaction, add 0.5 g of active charcoal and stir for 30 min. Cool to 25° C. and filter via a 0.4 micrometer membrane filter. Remove volatiles by rotovap (40° C./100 pascal) to yield a clear and light yellow brown liquid. ¹H-NMR (CDCl₃): d.8.61; (S, 2H), 8.45; (d, 2H), 8.20; (d, 2H), 7.70; (m, 4H), 5.68; (S, 2H), 4.62; (m, 8H), 4.05; (2H), 1.42; (2H), 1.28; (9H), 0.56; (2H).

### Example 1

Example (Ex) 1 has an average chemical structure of the following form of structure (I):

(HSiO_{3/2})_{0.56}(EpSiO_{3/2})_{0.17}(AnSiO_{3/2})_{0.27}[(ZO)ₓ(Ep)SiO_{(3-x)/2}]_{d}[(ZO)_{y}(An*)SiO_{(3-y)/2}]ₑ

where the material has a weight-average molecular weight of 4,920 and a polydispersity (PDI) of 3.05 as determined by GPC, and the Si—OZ content is less than one mol %.

Prepare Ex 1 in the following manner: Add 1000 grams (g) of HSQ Resin solution consisting of 75 wt % HSQ Resin in 25 wt % toluene, with wt % relative to HSQ Resin solution weight) to a three-liter flask. Add 107.8 g of allyl glycidyl ether, 331.6 g of 9-(hydroxymethyl)anthracene, and 0.080 g of Karstedt's Platinum catalyst. Stir the mixture at 80° C. and monitor the reaction by ¹H nuclear magnetic resonance (NMR) spectroscopy. After 6 hours stirring at 80° C. add 10 g of active carbon to the solution and stir an additional hour at 80° C. and then let cool to 25° C. Filter the solution through a 0.45-micrometer polytetrafluoroethylene (PTFE) filter and solvent-exchange to PGMEA using a rotovap (40° C./133 pascal). Dilute the resulting PGMEA solution to 30 wt % solids (non-volatile content, “NVC”, at 120° for 30 minutes) and then filter through a 0.2-micrometer PTFE filter to achieve final product. Store in a high density polyethylene bottle. The solution is primarily Example 1 but also contains a small amount of the following free isomerized monomers—0.6 wt % of A and 1.5 wt % of B as determined by ¹H NMR:

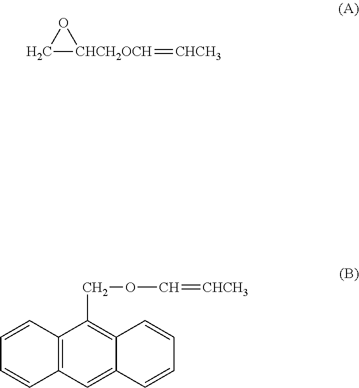

### Example 2

Ex 2 has an average chemical structure of the following form of structure (I):

(HSiO_{3/2})_{0.59}(EpSiO_{3/2})_{0.17}(AnSiO_{3/2})_{0.24}[(ZO)ₓ(Ep)SiO_{(3-x)/2}]_{d}[(ZO)_{y}(An*)SiO_{(3-y)/2}]ₑ

where the material has a weight-average molecular weight of 4,857 and a PDI of 3.03 as determined by GPC, and the Si—OZ content is less than one mol %.

Prepare Ex 2 in like manner as Ex 1 except use 100 grams (g) of HSQ Resin solution (25 wt % in toluene), 10.78 g of allyl glycidyl ether, 33.16 g of 9-(hydroxymethyl)anthracene, 0.024 g of Karstedt's Platinum catalyst, and 2.0 g of activated carbon.

Store in a high density polyethylene bottle. The solution is primarily Example 2 but also contains a small amount free isomerized monomers A (0.5 wt %) and B (1.3 wt %) as determined by ¹H NMR.

### Example 3

Ex 3 has an average chemical structure of the following form of structure (I):

(HSiO_{3/2})_{0.68}(EpSiO_{3/2})_{0.17}(AnSiO_{3/2})_{0.15}[(ZO)ₓ(Ep)SiO_{(3-x)/2}]_{d}[(ZO)_{y}(An*)SiO_{(3-y)/2}]ₑ

where the material has a weight-average molecular weight of 5,554 and a PDI of 3.12 as determined by GPC, and the Si—OZ content is less than one mol %.

Prepare Ex 3 in like manner as Ex 1 except use 500-milliter flask with 100 grams (g) of HSQ Resin solution (25 wt % in toluene), 10.78 g of allyl glycidyl ether, 19.91 g of 9-(hydroxymethyl)anthracene, 0.024 g of Karstedt's Platinum catalyst, and 2.0 g of activated carbon.

Store in a high density polyethylene bottle. The solution is primarily Example 2 but also contains a small amount free isomerized monomers A (0.5 wt %) and B (1.0 wt %) as determined by ¹H NMR.

### Example 4

Ex 4 has an average chemical structure of the following form of structure (I):

(HSiO_{3/2})_{0.53}(CHEpSiO_{3/2})_{0.20}(AnSiO_{3/2})_{0.27}[(ZO)ₓ(CHEp)SiO_{(3-x)/2}]_{d}[(ZO)_{y}(An)SiO_{(3-y)/2}]ₑ

where the material has a weight-average molecular weight of 7,821 and a PDI of 4.50 as determined by GPC, and the Si—OZ content is less than one mol %.

Prepare Ex 4 in like manner as Ex 1 except use 500-milliter flask with 100 grams (g) of HSQ Resin solution (25 wt % in toluene), 10.78 g of 4-vinyl-1-cyclohexene 1,2-epoxide instead of allyl glycidyl ether, 33.16 g of 9-(hydroxymethyl) anthracene, 0.024 g of Karstedt's Platinum catalyst, and 2.0 g of activated carbon.

Store in a high density polyethylene bottle. The solution is primarily Example 2 but also contains a small amount free isomerized monomer B (1.7 wt %) as determined by ¹H NMR.

### Example 5

Ex 5 has an average chemical structure of the following form of structure (I):

(HSiO_{3/2})_{0.63}(CHEpSiO_{3/2})_{0.20}(AnSiO_{3/2})_{0.17}[(ZO)ₓ(CHEp)SiO_{(3-x)/2}]_{d}[(ZO)_{y}(An)SiO_{(3-y)/2})]ₑ

where the material has a weight-average molecular weight of 33,966 and a PDI of 18.65 as determined by GPC, and the Si—OZ content is less than one mol %.

Prepare Ex 5 in like manner as Ex 1 except use 500-milliter flask with 100 grams (g) of HSQ Resin solution (25 wt % in toluene), 10.78 g of 4-vinyl-1-cyclohexene 1,2-epoxide instead of allyl glycidyl ether, 22.12 g of 9-(hydroxymethyl) anthracene, 0.024 g of Karstedt's Platinum catalyst, and 2.0 g of activated carbon.

Store in a high density polyethylene bottle. The solution is primarily Example 2 but also contains a small amount free isomerized monomer B (1.0 wt %) as determined by ¹H NMR.

### Example 6

Ex 6 has an average chemical structure of the following form of structure (I):

(HSiO_{3/2})_{0.55}(CHEpSiO_{3/2})_{0.16}(NaphSiO_{3/2})_{0.30}[(ZO)ₓ(CHEp)SiO_{(3-x)/2}]_{d}[(ZO)_{y}(Naph)SiO_{(3-y)/2}]ₑ

where the material has a weight-average molecular weight of 9,538 and a PDI of 3.31 as determined by GPC, and the Si—OZ content is less than one mol %.

Prepare Ex 6 in like manner as Ex 1 except use 250-milliter flask with 100 grams (g) of HSQ Resin solution (25 wt % in toluene), 8.79 g of 4-vinyl-1-cyclohexene 1,2-epoxide instead of allyl glycidyl ether, 21.84 g of vinyl naphthalene instead of 9-(hydroxymethyl) anthracene, 0.024 g of Karstedt's Platinum catalyst, and 2.0 g of activated carbon. Store in a high density polyethylene bottle.

### Example 7

Ex 7 has an average chemical structure of the following form of structure (I):

(HSiO_{3/2})_{0.50}(CHEpSiO_{3/2})_{0.20}(TPSSiO_{3/2})_{0.30}[(ZO)ₓ(CHEp)SiO_{(3-x)/2}]_{d}[(ZO)_{y}(TPS)SiO_{(3-y)/2}]ₑ

where the material has a weight-average molecular weight of 9,264and a PDI of 9.00 as determined by GPC, and the Si—OZ content is less than one mol %.

Prepare Ex 7 in like manner as Ex 1 except use 250-milliter flask with 50.00 grams (g) of HSQ Resin solution (25 wt % in toluene), 8.84 g of 4-vinyl-1-cyclohexene 1,2-epoxide instead of allyl glycidyl ether, 25.51 g of 1,1,-dimethyl-3,3,3-triphenyl-1-vinyldisiloxane instead of 9-(hydroxymethyl) anthracene, 0.024 g of Karstedt's Platinum catalyst, and 2.0 g of activated carbon. Store in a high density polyethylene bottle.

### Example 8

Ex 8 has an average chemical structure of the following form of structure (I):

(HSiO_{3/2})_{0.60}(CHEpSiO_{3/2})_{0.20}(TPSSiO_{3/2})_{0.20}[(ZO)ₓ(CHEp)SiO_{(3-x)/2}]_{d}[(ZO)_{y}(TPS)SiO_{(3-y)/2}]ₑ

where the material has a weight-average molecular weight of 13,538 and a PDI of 5.98 as determined by GPC, and the Si—OZ content is less than one mol %.

Prepare Ex 8 in like manner as Ex 1 except use 250-milliter flask with 50.00 grams (g) of HSQ Resin solution, 5.84 g of 4-vinyl-1-cyclohexene 1,2-epoxide instead of allyl glycidyl ether, 17.02 g of 1,1,-dimethyl-3,3,3-triphenyl-1-vinyldisiloxane instead of 9-(hydroxymethyl)anthracene, 0.024 g of Karstedt's Platinum catalyst, and 2.0 g of activated carbon. Store in a high density polyethylene bottle.

### Example 9

Ex 9 has an average chemical structure of the following form of structure (I):

(HSiO_{3/2})_{0.45}(CHEpSiO_{3/2})_{0.20}(TPSSiO_{3/2})_{0.35}[(ZO)ₓ(CHEp)SiO_{(3-x)/2}]_{d}[(ZO)_{y}(TPS)SiO_{(3-y)/2}]ₑ.

Prepare Ex 9 in like manner as Ex 8 except use 29.80 g of 1,1,-dimethyl-3,3,3-triphenyl-1-vinyldisiloxane, 2.0 g of active carbon. Ex 9 has a weight average molecular weight of 9562 and a polydispersity of 4.32 and an Si—OZ content of less than 1.0 mol % relative to silicon atom concentration.

### Example 10

(HSiO_{3/2})_{0.40}(CHEpSiO_{3/2})_{0.20}(TPSSiO_{3/2})_{0.40}[(ZO)ₓ(CHEp)SiO_{(3-x)/2}]_{d}[(ZO)_{y}(TPS)SiO_{(3-y)/2}]ₑ.

Prepare Ex 10 in like manner as Ex 8 except use 34.04 g of 1,1,-dimethyl-3,3,3-triphenyl-1-vinyldisiloxane, 2.0 g of active carbon. Ex 9 has a weight average molecular weight of 9728 and a polydispersity of 4.56 and an Si—OZ content of less than 1.0 mol % relative to silicon atom concentration.

### Example 11

Ex 11 has an average chemical structure of the following form of structure (I):

(HSiO_{3/2})_{0.55}(CHEpSiO_{3/2})_{0.15}(TBPSiO_{3/2})_{0.30}[(ZO)ₓ(CHEp)SiO_{(3-x)/2}]_{d}[(ZO)_{y}(TBP)SiO_{(3-y)/2}]ₑ

where the material has a weight-average molecular weight of 8,350 and a PDI of 3.12 as determined by GPC and the Si—OZ content is less than one mol %.

Prepare Ex 11 in like manner as Ex 1 except use 250-milliter flask with 100.00 grams (g) of HSQ Resin solution (25 wt % in toluene), 8.79 g of 4-vinyl-1-cyclohexene 1,2-epoxide instead of allyl glycidyl ether, 54.40 g of 2,4,6-tribromophenyl ally ether instead of 9-(hydroxymethyl) anthracene, 0.024 g of Karstedt's Platinum catalyst, and 2.0 g of activated carbon. Store in a high density polyethylene bottle.

### Example 12

Ex 12 has an average chemical structure of the following form of structure (I):

(HSiO_{3/2})_{0.55}(CHEpSiO_{3/2})_{0.15}(PBPSiO_{3/2})_{0.30}[(ZO)ₓ(CHEp)SiO_{(3-x)/2}]_{d}[(ZO)_{y}(PBP)SiO_{(3-y)/2}]ₑ

where the material has a weight-average molecular weight of 8,215 and a PDI of 3.08 as determined by GPC, and the Si—OZ content is less than one mol %.

Prepare Ex 12 in like manner as Ex 1 except use 250-milliter flask with 100.00 grams (g) of HSQ Resin solution (25 wt % in toluene), 8.79 g of 4-vinyl-1-cyclohexene 1,2-epoxide instead of allyl glycidyl ether, 74.85 g of pentabromophenyl allyl ether instead of 9-(hydroxymethyl)anthracene, 0.024 g of Karstedt's Platinum catalyst, and 2.0 g of activated carbon. Store in a high density polyethylene bottle.

### Example 13

Ex 13 has an average chemical structure of the following form of structure (I):

(HSiO_{3/2})_{0.55}(MASiO_{3/2})_{0.15}(AnSiO_{3/2})_{0.30}[(ZO)ₓ(MA)SiO_{(3-x)/2}]_{d}[(ZO)_{y}(An)SiO_{(3-y)/2}]ₑ

where the SiOZ content is 12.5 mol %, the material having a weight-average molecular weight of 17,027 and a PDI of 5.89 as determined by GPC.

Prepare Ex 13 by combining in a 500-milliliter flask 50 g of PGMEA, 20.0 g of (3-(Anthracen-9-ylmethoxy)propyl)triethoxysilane, 12.4 g of trichlorosilane and 6.21 g of Methacryloxypropyl trimethoxysilane. While stirring, add to this mixture a solution of 200 grams of PGMEA and 6.61 g of water over a one-hour period at 20° C. Continue stirring at 20°° C. for 2 hours after the addition is complete. Transfer the resulting resin solution to a 1-liter separation funnel and wash with 100 milliliters of deionized water. Discard the phase separated water. Transfer the remaining cloudy solution to a 1-liter pear flask and add approximately 20 g of ethanol. Strip the solution using a rotovap at 40° C. and 500 pascals pressure, dilute to 30 wt % solids with PGMEA and then filter through a 0.20 micrometer PTFE filter to obtain Ex 13. Store in a HDPE bottle.

### Example 14

Ex 14 has an average chemical structure of the following form of structure (I):

(HSiO_{3/2})_{0.55}(MASiO_{3/2})_{0.15}(NapSiO_{3/2})_{0.30}[(ZO)ₓ(MA)SiO_{(3-x)/2}]_{d}[(ZO)_{y}(Nap)SiO_{(3-y)/2}]ₑ

where the Si—OZ content is 10.9 mol %, the material having a weight-average molecular weight of 11,884 and a PDI of 6.53 as determined by GPC.

Prepare Ex 14 by combining in a 500-milliliter flask 50 g of PGMEA, 5.0 g of 1-naphyltrimethoxysilane, 9.93 g of trichlorosilane and 10.0 g of Methacryloxypropyl trimethoxysilane. While stirring, add to this mixture a solution of 200 grams of PGMEA and 5.27 g of water over a one-hour period at 20° C. Continue stirring at 20° C. for 2 hours after the addition is complete. Transfer the resulting resin solution to a 1-liter separation funnel and wash with 100 milliliters of deionized water. Discard the phase separated water. Transfer the remaining cloudy solution to a 1-liter pear flask and add approximately 20 g of ethanol. Strip the solution using a rotovap at 40° C. and 500 pascals pressure, dilute to 30 wt % solids with PGMEA and then filter through a 0.20 micrometer PTFE filter to obtain Ex 14. Store in a HDPE bottle.

### Example 15

Ex 15 has an average chemical structure of the following form of structure (I):

(HSiO_{3/2})_{0.55}(VESiO_{3/2})_{0.15}(AnSiO_{3/2})_{0.30}[(ZO)ₓ(VE)SiO_{(3-x)/2}]_{d}[(ZO)_{y}(An)SiO_{(3-y)/2}]ₑ

where “VE” corresponds to CH₂═CH—O(CH₂)₄—O—, the Si—OZ content is 7.8 mol %, the material having a weight-average molecular weight of 5,946 and a PDI of 3.34 as determined by GPC.

Prepare Ex 15 by combining in a 500-milliliter flask 100 g of HSQ Resin (25 wt % in toluene), 33.16 g of 9-allyloxyanthracene, and 0.016 g Karstedt's Platinum catalyst. Stir the mixture for 4 hours at 80° C. and then cool to 23° C. Filter the solution and then add 8.22 g of 1,4-butanediol vinyl ether and 0.5 g of DBTDL. Stir at 60° C. for 3 hours and then add 2.0 g of active charcoal. Stir for an additional one hour and then cool to 25° C. Filter the solution and vacuum strip. Add PGMEA to form a 30 wt % solution of solids in PGMEA. Filter the solution through a 0.2 micrometer PTFE filter to obtain Ex 15. Store in a HDPE bottle.

### Comparative Example A

Comparative Example (Comp Ex) A has an average chemical structure of the following form of structure (I):

(HSiO_{3/2})_{0.75}(EpSiO_{3/2})_{0.25}[(ZO)ₓ(Ep)SiO_{(3-x)/2}]_{d}

where subscript d is less than 0.01 over all values of x, the material having a weight-average molecular weight of 7,034 and a PDI of 3.21 as determined by GPC.

Prepare Comp Ex A in by adding to a one-liter flask 200 g of HSQ Resin solution (25 wt % in toluene), 32.3 g of ally glycidyl ether, and 0.24 g Karstedt's Platinum catalyst. Stir the mixture for two hours at 80° C. Add 5 wt % active charcoal to the solution and continue mixing for one hour at 23° C. Filter the solution and subject to vacuum stripping and solvent exchange with PGMEA to form a 30 wt % resin solution. Filter thee resin solution through a 0.2 micrometer PTFE filter and store in a high density polyethylene bottle.

### Comparative Example B

Comp Ex B has an average chemical structure of the following form of structure (I):

(HSiO_{3/2})_{0.75}(CHEpSiO_{3/2})_{0.25}[(ZO)ₓ(CHEp)SiO_{(3-x)/2}]_{d}

where subscript d is less than 0.01 over all values of x, the material having a weight-average molecular weight of 10,520 and a PDI of 4.76 as determined by GPC.

Prepare Comp Ex B in like manner as Comp Ex A except use a 500 milliliter flask, 100 g HSQ resin solution (25 wt % in toluene), 14.6 g 4-vinyl-1-cyclohexene 1,2-epoxide instead of allyl glycidyl ether, and 0.12 g of Karstedt's Platinum catalyst.

### Comparative Example C

Comp Ex C has an average chemical structure of the following form of structure (I):

(HSiO_{3/2})_{0.60}(STSiO_{3/2})_{0.20}(CHEpSiO_{3/2})_{0.20}[(ZO)ₓ(CHEp)SiO_{(3-x)/2}]_{d}

where “ST” is —CH₂CH₂Ph and Ph is phenyl, subscript d is less than 0.01 over all values of x, the material having a weight-average molecular weight of 7,520 and a PDI of 4.76 as determined by GPC.

Prepare Comp Ex C in like manner as Comp Ex A except use a 500 milliliter flask, 100 g HSQ resin (25 wt % in toluene), 11.7 g 4-vinyl-1-cyclohexene 1,2-epoxide instead of allyl glycidyl ether, and 9.82 styrene, and 0.12 g of Karstedt's Platinum catalyst.

### Comparative Example D

Comp Ex D has an average chemical structure of the following form of structure (I):

(HSiO_{3/2})_{0.50}(PhSiO_{3/2})_{0.38}[(HO)ₓ(Ph)SiO_{(3-x)/2}]_{0.12}

Where “Ph” refers to a phenyl group and Comp Ex D has a weight-average molecular weight of 21,800 and a PDI of 3.16 as determined by GPC and the Si—OZ content is 12.0 mol %.

Prepare Comp Ex D by hydrolysis of chlorosilanes according to the teachings in U.S. Pat. No. 7,756,384.

### Comparative Example E

Comp Ex E has an average chemical structure of the following form of structure (I):

(MeSiO_{3/2})_{0.38}(PhSiO_{3/2})_{0.34}[(HO)ₓ(Me)SiO_{(3-x)/2}]_{0.12}[(HO)ₓ(Ph)SiO_{(3-x)/2}]_{0.16}

Where “Ph” refers to a phenyl group and Comp Ex E has a weight-average molecular weight of 2,430 and a PDI of 1.55 as determined by GPC and the SiOOZ content is 28.0 mol %.

Prepare Comp Ex E by hydrolysis of 18.69 g of methyltrichlorosilane and 26.44 g of phenyltrichlorosilane according to the teachings in U.S. Pat. No. 7,756,384.

### Comparative Example F

Comp Ex F is a blend of Comp Ex D and 3-glycidyloxypropyl) trimethoxysilane. Prepare by combining 8 g of Comp Ex D as a 30 wt % solution in PGMEA and 2 g of (3-glycidyloxypropyl)trimethoxysilane and mixing at 25° C. to form a homogeneous mixture.

### Example 16

Prepare Ex 16 by blending in a 100 milliliter high density polyethylene bottle 40 g of Ex 1 and 10 g of Comp Ex 1 to form a homogeneous mixture.

### Characterization of Exs and Comp Exs

Characterize each of Ex and Comp Ex in a negative photoresist composition. Prepare the negative photoresist composition for each of Ex 1-12 and 16 and each Comp Ex by combining with a 20 g sample of each Ex and Comp Ex, 0.06 g of (p-Isopropylphenyl)(p-methylphenyl)iodonium tetrakis(pentafluorophenyl)borate, which is a photoacid generator (PAG). Mix until the PAG is dissolved. Filter the mixture through a 0.2 micrometer PTFE filter to obtain a negative photoresist composition comprising 30 wt % resin and 1 wt % PAG in PGMEA solvent.

Prepare a negative photoresist composition for Exs 13-15 by forming a composition by adding to a 30 wt % solution of resin 3 wt % of a Photoinitiator 1 and mixing to form a uniform solution and then filter through a 0.2 micrometer PTFE filter to obtain a negative photoresist composition comprising 30 wt % resin and 1 wt % Photoinitiator 1 in PGMEA.

Spin coat each negative photoresist composition onto standard single-side 4-inch polished low resistivity wafers or double-sided polished Fourier transform infrared (FTIR) wafers at a spin speed of 1500 revolutions per minute, acceleration speed of 5000 and a time of 20 seconds unless otherwise noted. Using a Karl Suss CT62 spin coater. Pre-bake the wafer at 90° C. for 60 seconds, followed by broadband ultraviolet (UV) irradiation (0.5 Joules per square meter) using a fusion UV device. Post-bake the spin-coated wafer at 90° C. for 60 seconds.

Characterize the negative photoresist composition coating in the following ways both “as spun” prior to UV irradiation and “after curing” by UV irradiation and post-baking.
Glass Transition Temperature (Tg). Measure Tg of dry resin samples. Prepare dry resin samples of a resin by drying the resin in a vacuum over at 80° C. and 133 pascal pressure for 10 hours. Measure the Tg of the dried resin using a DSC-Q2000 instrument using 6-10 milligrams of rein and a ramp temperature of 10° C. per minute over a range of 23° C. to 200° C.
Coating Quality. If the coating is free of obvious defects and uniform it is “good”. If the coating has visible defects, is no-uniform and has a sticky surface it is “bad”.
Coating Thickness. Determine the coating thickness by ellipsometry using an ellipsometer from J.A. Woollam Company using a light source with a wavelength over a range of 200 to 900 nanometers. The thickness is determined as the average of 9 measurements on the coated wafer. Also determine standard deviation (SD) of the 9 measurements.
Refractive Index. Determine refractive index (RI) by ellipsometry while measuring coating thickness. Measure RI before and after curing using the procedure for measuring ellipsometry but report the RI measured at a light wavelength of 632 nanometers.
Solvent and Developer Solubility. Determine the solubility of the coating in both PGMEA and TMAH. For PGMEA, rinse the coated wafer while spinning (1500 revolutions per minute, 5000 acceleration, 20 seconds on Karl Suss CT62 spin coater) with approximately 20 milliliters PGMEA. Measure the coating thickness before and after rinsing and report solubility as a % coating thickness lost by rinsing. For TMAH, soak the coated wafer is an aqueous solution of TMAH (2.8 wt % TMAH) for 5 minutes at 30° C. Measure the coating thickness before and after soaking and report solubility as a % coating thickness lost by soaking. A loss of at least 98.0% indicates solubility in that solvent.

Table 2 presents characterization of the Exs and Table 3 presents characterization of the Comp Exs. “ND” means not determined.

TABLE 2

| | | | | | | | PGMEA | TMAH |
|---|---|---|---|---|---|---|---|---|
| | As Spun | | | | | | Solubility | Solubility |
| | or After | Tg | Coating | Thickness | | | (% thickness | (% thickness |
| Sample | Curing | (° C.) | Quality | (Å) | SD | RI | loss) | loss) |
| Ex 1 | As Spun | >150 | Good | 11,233 | 55 | 1.620 | 100 | 100 |
| | After | | Good | 11,076 | 102 | 1.621 | 0.00 | 0.21 |
| | Curing | | | | | | | |
| Ex 2 | As Spun | >150 | Good | 11,159 | 12 | 1.598 | 100 | 100 |
| | After | | Good | 11,050 | 31 | 1.593 | 0.00 | 0.11 |
| | Curing | | | | | | | |
| Ex 3 | As Spun | >150 | Good | 11,101 | 15 | 1.558 | 100 | 100 |
| | After | | Good | 10,338 | 127 | 1.558 | 0.00 | 0.00 |
| | Curing | | | | | | | |
| Ex 4 | As Spun | 135 | Good | 11,087 | 50 | 1.628 | 100 | 100 |
| | After | | Good | 10,896 | 36 | 1.633 | 0.00 | 0.00 |
| | Curing | | | | | | | |
| Ex 5 | As Spun | 137 | Good | 18,520 | 135 | 1.580 | 100 | 100 |
| | After | | Good | 20,756 | 462 | 1.584 | 0.00 | 19.80 |
| | Curing | | | | | | | |
| Ex 6 | As Spun | >150 | Good | 11,245 | 37 | 1.575 | 100 | 100 |
| | After | | Good | 11,250 | 59 | 1.570 | 0.67 | 1.20 |
| | Curing | | | | | | | |
| Ex 7 | As Spun | 150 | Good | 12,950 | 56 | 1.570 | 100 | 97.00 |
| | After | | Good | 12,887 | 120 | 1.578 | 0.00 | 1.47 |
| | Curing | | | | | | | |
| Ex 8 | As Spun | 150 | Good | 12,976 | 34 | 1.551 | 100 | 100 |
| | After | | Good | 12,948 | 37 | 1.550 | 0.00 | 0.17 |
| | Curing | | | | | | | |
| Ex 9 | As Spun | >150 | Good | 11,234 | 36 | 1.580 | 100 | 65.10 |
| | After | | Good | 11.248 | 40 | 1.578 | 0.00 | 0.45 |
| | Curing | | | | | | | |
| Ex 10 | As Spun | >150 | Good | 11,356 | 46 | 1.585 | 100 | 20.10 |
| | After | | Good | 11,420 | 32 | 1.583 | 0.00 | 0.35 |
| | Curing | | | | | | | |
| Ex 11 | As Spun | >150 | Good | 12,505 | 23 | 1.590 | 100 | 100 |
| | After | | Good | 11,950 | 45 | 1.595 | 0.00 | 1.50 |
| | Curing | | | | | | | |
| Ex 12 | As Spun | >150 | Good | 10,235 | 28 | 1.620 | 100 | 100 |
| | After | | Good | 10,321 | 42 | 1.625 | 0.00 | 1.10 |
| | Curing | | | | | | | |
| Ex 13 | As Spun | >150 | Good | 13,205 | 75 | 1.631 | 100 | 100 |
| | After | | Good | 13,256 | 89 | 1.628 | 0.00 | 1.20 |
| | Curing | | | | | | | |
| Ex 14 | As Spun | >150 | Good | 10,546 | 45 | 1.584 | 100 | 100 |
| | After | | Good | 10,567 | 78 | 1.591 | 0.00 | 0.00 |
| | Curing | | | | | | | |
| Ex 15 | As Spun | >150 | Good | 7,394 | 25 | 1.624 | 100 | 100 |
| | After | | Good | 7,422 | 43 | 1.638 | 0.00 | 2.70 |
| | Curing | | | | | | | |
| Ex 16 | As Spun | >150 | Good | 11,101 | 15 | 1.577 | 100 | 100 |
| | After | | Good | 10,293 | 49 | 1.577 | 0.00 | 0.40 |
| | Curing | | | | | | | |

TABLE 3

| | | | | | | | PGMEA | TMAH |
|---|---|---|---|---|---|---|---|---|
| | As Spun | | | | | | Solubility | Solubility |
| | or After | Tg | Coating | Thickness | | | (% thickness | (% thickness |
| Sample | Curing | (° C.) | Quality | (Å) | SD | RI | loss) | loss) |
| Comp | As Spun | >150 | Good | 9,484 | 32 | 1.456 | 100 | 100 |
| Ex A | After | | Good | 9,455 | 32 | 1.457 | 0.00 | 0.39 |
| | Curing | | | | | | | |
| Comp | As Spun | >150 | Good | 13,056 | 78 | 1.451 | 100 | 100 |
| Ex B | After | | Good | 12,890 | 67 | 1.452 | 0.00 | 0.36 |
| | Curing | | | | | | | |
| Comp | As Spun | ND | Good | 13,100 | 56 | 1.497 | 100 | 100 |
| Ex C | After | | Good | 12,980 | 43 | 1.502 | 0.00 | 0.00 |
| | Curing | | | | | | | |
| Comp | As Spun | ND | Good | 14,500 | 34 | 1.529 | 100 | 98.5 |
| Ex D | After | | Good | 14,356 | 45 | 1.529 | 100 | 98.0 |
| | Curing | | | | | | | |
| Comp | As Spun | ND | Good | 6,200 | 15 | 1.515 | 100 | 2.5 |
| Ex E | After | | Good | 6,120 | 10 | 1.520 | 100 | 2.6 |
| | Curing | | | | | | | |
| Comp | As Spun | ND | Bad | 12,350 | 630 | 1.510 | 100 | 100 |
| Ex F | After | | Bad | 12,210 | 436 | 1.510 | 12.50 | 63.5 |
| | Curing | | | | | | | |

1. A composition comprising a photocurable resin, wherein the photocurable resin has a weight-average molecular weight in a range of 3,000-50,000 Daltons, a glass transition temperature of at least 100 degrees Celsius and comprises the following siloxane units: 50-80 mole-percent (HSiO_{3/2}), 10 to 30 mole-percent (R*SiO_{3/2}), 10 to 40 mole-percent (Ar*SiO_{3/2}), and 20.0 mole-percent or less of Si—OZ content where mole-percent values are relative to moles of silicon atoms in the photocurable resin, R* is a photocurable group, Ar* in each occurrence is selected from a group of halogen-substituted aryl groups and polyaryl groups; and Z in each occurrence is selected from hydrogen and alkyl groups.

2. The composition of claim 1, where the resin further comprises wherein in each occurrence the photocurable group is independently selected from a group consisting of epoxy-containing groups, acrylate-containing groups, acryloxy groups, vinylether groups, and vinyl groups.

3. The composition of claim 2, wherein the photocurable group is independently in each occurrence selected from an epoxycyclohexylethyl group, glycidoxypropyl group and methacryloxopropyl groups.

4. The composition of claim 1, wherein the —Ar* group in each occurrence is independently selected from a group consisting of those having the following chemical structures (i)-(iv):

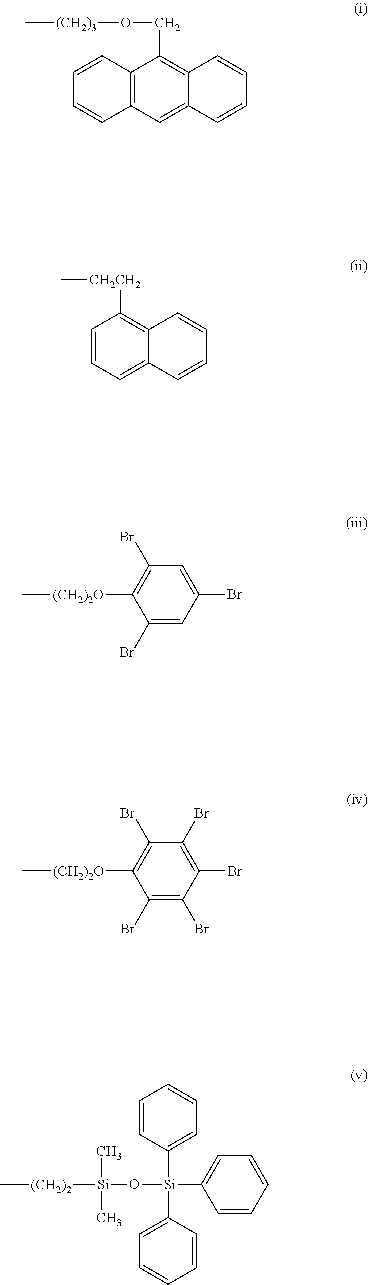

5. The composition of claim 1, wherein the composition is a negative photoresist composition that comprises 10 to 50 weight-percent of the photoresist resin of any one previous claim, one to 3 weight-percent of a photoinitiator at a concentration, and 49-89 weight-percent of a solvent, where weight-percentages are relative to photoresist composition weight.

6. A process for using the negative photoresist composition of claim 5 to prepare an optical light emitting diode display, the process comprising the following steps:
(a) providing a substrate that comprises multiple diodes;
(b) coating the negative photoresist composition of claim 5 onto the substrate that comprises multiple diode pixels;
(c) exposing the negative photoresist composition that resides over the diode pixels to light to cure the photoresist resist resin in the negative photoresist composition to form lens patches over the diode pixels;
(d) rinsing away the unexposed/uncured negative photoresist composition with an aqueous alkali solution;
(e) applying a planarization polymer over the substrate and lens patches; and
(f) curing the planarization polymer.

7. The process of claim 6, wherein step (b) includes spin-coating the negative photoresist composition of claim 5 onto the substrate.

8. The process of claim 1, wherein step (c) includes exposing the negative photoresist composition to light through a mask to selectively expose certain portions of the negative photoresist composition to light to cause curing of the photoresist in the negative photoresist composition that is exposed to the light.

9. The process of claim 1, wherein the aqueous alkali solution comprises tetramethylammonium hydroxide.

10. The process of claim 1, wherein the planarization polymer is a curable polymer having a refractive index at least 0.1 lower than the cured photoresist resin.
